(19) United States
(12) Patent Application Publication
(10) Pub. No.: US 2020/0139826 A1
(43) Pub. Date: May 7, 2020

(54) HOUSING FOR ACCOMODATING POWER ELECTRONICS FOR A VEHICLE AND POWER ELECTRONICS SYSTEM

(71) Applicant: ZF Friedrichshafen AG, Friedrichshafen (DE)

(72) Inventors: Ajoy PALIT, Bremen (DE); Thomas ERDMANN, Stemwede (DE)

(73) Assignee: ZF Friedrichshafen AG, Friedrichshafen (DE)

(21) Appl. No.: 16/483,647

(22) PCT Filed: Jan. 2, 2018
(86) PCT No.: PCT/EP2018/050025

§ 371 Date: Aug. 5, 2019

(30) Foreign Application Priority Data
Feb. 6, 2017 (DE) 10 2017 201 843.7

(51) Int. Cl. B60L 50/64; H02J 7/00; B60L 58/26; H05K 7/20

(52) U.S. Cl. CPC B60L 50/64; H02J 7/0042; H05K 7/209; H05K 7/20854; B60L 58/26

(57) ABSTRACT

The invention relates to a housing (100) for accommodating power electronics (102) for a vehicle, wherein the housing (100) comprises a well (104) made of a plastic material, and a heat sink (110) made of a thermally conductive metal material, wherein the heat sink (110) comprises an inner part (112) located on an inner surface of the well (104) and an outer part (114) located on an outer surface of the well (104), and at least one Peltier element (118) is located between the inner part (112) and the outer part (114).

The present invention relates to a device of the type according to the independent claim.

A charger for the batteries in an electric vehicle is a power electronics system and comprises power electronics, which produce waste heat from electrical losses. The waste heat is accumulated in a housing for the charger, and in adverse conditions can result in temperatures of the charger that are higher than acceptable operating temperatures for the power electronics.

Based on this, the present invention creates an improved housing for the power electronics in a vehicle, and an improved power electronics system according to the independent claims. Advantageous embodiments can be derived from the dependent claims and the following descriptions.

A heat sink has a warm side and a cold side. Heat flows from the warm side to the cold side. The warm side can be in a housing, where it absorbs heat, which then flows to the cold side, where the heat is discharged into the environment. The heat flow can be increased if there is a heat pump between the warm side and the cold side. A Peltier element is particularly suitable for the heat pump, because it has no moving parts.

A housing for accommodating a power electronics for a vehicle is presented, wherein the housing comprises the following features:

a well made of plastic;

a heat sink made of a thermally conductive metal material, wherein the heat sink has an inner part located on an inner surface of the well, and an outer part located on an outer surface of the well; and

at least one Peltier element located between the inner part and the outer part.

A power electronics module can be understood to be, e.g., a converter circuit for generating a charging current for a rechargeable battery. The inner part and the outer part of the heat sink can be connected to one another in a thermally conductive manner. The heat sink can be made of an aluminum alloy, for example.

A contact surface of the heat sink in contact with the well can form a contour of the well. The shape of the heat sink can be adapted to the contour of the well. As a result, the housing can have a compact design.

The heat sink can be placed on an edge of the well. The heat sink can cover an edge of the well. Placing it on the edge simplifies the assembly.

The heat sink can encompass the edge in an annular manner. A large thermal transition surface can be obtained with a circumferential heat sink.

The heat sink can be attached to the well using heat conducting clips. The clips can be located in a wall of the well. The clips can contain a threading for screwing the heat sink thereto.

The well can be sealed in an airtight manner with a glass plate. The glass plate can be referred to as a lid for the housing. Operating and display elements can be located on the glass plate.

The Peltier element can be located on the inner surface of the well. As a result of the internal placement, the Peltier element can be supplied with electricity by the power electronics. The inner part is also therefore cold.

The heat sink can have fins for increasing the surface area. A good heat transfer can be obtained with a large surface area.

Furthermore, a power electronics system for a vehicle is proposed that has a housing according to the approach presented herein, in which power electronics are accommodated inside the housing in an airtight manner, wherein the Peltier element is connected to the power electronics and thus supplied with electricity such that the inner part is cold and the outer part is warm when in operation.

The power electronics can form a charger for an electric drive in a vehicle. The power electronics system can form a charger for an electric vehicle and/or a hybrid vehicle. As a result of the airtight, dustproof, and moisture proof housing, the charger can be used in harsh environmental conditions.

Exemplary embodiments of the approach presented herein are illustrated in the drawings and explained in greater detail in the following description. Therein:

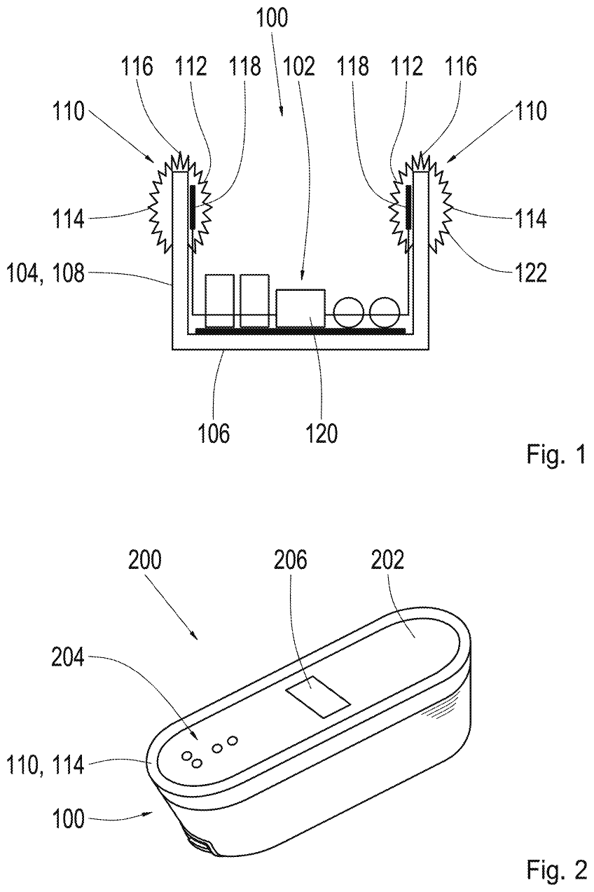

FIG. 1 shows a sectional view of a housing for accommodating a power electronics according to an exemplary embodiment of the present invention;

FIG. 2 shows a spatial illustration of a charger for a vehicle according to an exemplary embodiment of the present invention;

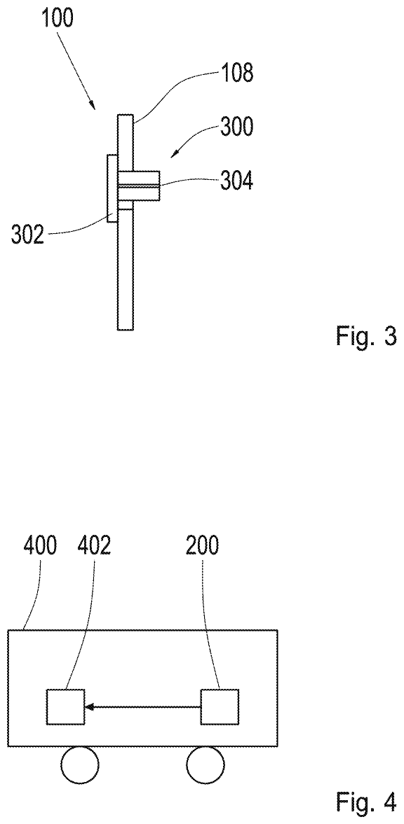

FIG. 3 shows an illustration of an attachment solution for a heat sink according to an exemplary embodiment of the present invention; and

FIG. 4 shows a schematic illustration of a vehicle that has a power electronics system according to an exemplary embodiment of the present invention.

In the following description of preferred exemplary embodiments of the present invention, the same or similar reference symbols are used for the elements shown in the figures that have similar functions, wherein the descriptions of these elements shall not be repeated.

FIG. 1 shows a sectional view of a housing 100 for housing power electronics 102 according to an exemplary embodiment of the present invention. The housing 100 comprises a well 104 made of a plastic material. The power electronics 102 can be placed on the base 106 of the well 104. In this illustration, the power electronics 102 are placed on the base 106 of the well. A heat sink 110 is placed on a wall 108 of the well 104 in the housing 100. The heat sink 110 is formed on a circumferential edge of the wall 108. The heat sink 110 has an inner part 112 located on an inner surface of the well 104 and an outer part 114 located on the outer surface of the well 104. In this example, the inner part 112 and the outer part 114 are connected to one another by a heat conducting thermal bridge 116. The thermal bridge 116 runs over the edge of the wall 108. Peltier elements 118 are placed between the inner part 112 and the outer part 114. The Peltier elements 118 transport heat from one side of the Peltier elements 118 to the other side of the Peltier elements 118 when electricity is supplied thereto. The Peltier elements 118 are connected to a control unit 120 that is part of the power electronics 102. The Peltier elements 118 are actuated by the control unit 120 such that they transport heat from the inner part 112 to the outer part 114.

In one exemplary embodiment, the heat sink 110 has fins 122, which increase the surface area of the heat sink 110 in order to obtain an improved thermal transition.

In other words, a more efficient mechanism for thermal discharge, or cooling, of a power electronics module 102 is presented, which is accommodated in a sealed, airtight, and thermally non-conductive (plastic) housing 100. This technology can be used for any power electronics accommodated in a sealed plastic housing 100.

An economical, simple innovative solution for such a heat discharge problem is presented herein for discharging heat generated by the electronics module 102 with a higher wattage, or electrical power, inside a sealed plastic housing 100.

The housing 100 is sealed against air, dust and moisture in the closed state. Without the heat sink 110, the heat discharge from the inside of the housing 100 to the outside is very slow, due to the power thermal conductivity of the plastic wall 108 and the glass plate on top, not shown here.

Without an active heat discharge, heat can accumulate inside the housing, resulting in a very high internal temperature. Consequently, the glass plate, which is in contact with hot air on the inside that can reach temperatures higher than 60° C. on the upper cover of the housing. At high temperatures in the interior of the housing, the service life of the current sensor and other electronic low voltage components is reduced, and the performance thereof diminishes quickly when subjected to high thermal loads.

The heat discharge can be obtained using a heat pipe filled with a suitable fluid, and by circulating the fluid with a small electromechanical pump located inside the heat pipe. Alternatively, thermal circulation can be obtained in the limited air supply filling the sealed plastic housing with a small rotary fan, or ventilator.

Heat pipes in combination with small electromechanical pumps do not provide an economical solution, and a motor may also have a short service life, due to the moving, or rotating, parts, requiring frequent maintenance, as well as generating audible noise. The use of a small fan with rotating blades is a somewhat more economical solution, which circulates the air inside the housing, and prevents hot spots from forming on the outside of the glass plate or the housing, but because of the moving parts, the fan has a service life of only 15,000 to 20,000 hours, and may require maintenance, as otherwise the efficiency deteriorates over time.

With the approach proposed herein, there are no rotating or moving parts, but it is possible to obtain air circulation inside the sealed housing 100 in order to avoid generating hot spots, and the heat is also transported quickly out of the housing 100.

With the approach proposed herein, an oval or annular, oblong heat sink 110 made of aluminum is placed on the housing 100. The heat sink 110 is located on the upper part of the housing 100, on the inside and outside of the substantially vertical plastic side walls 108. The heat that is generated is transported by the heat sink 110 out of the housing 100. The oblong oval aluminum heat sink 110 is installed using a simple technology, which seals the plastic housing 100 against air, dust, and moisture. Furthermore, there are at least two Peltier elements 118 on the inner wall of the housing 100 for a fast thermal transfer out of the housing 100. The Peltier elements 118 can be square or rectangular. The cold, or colder, side of each Peltier element 118 is thermally coupled to the inner oval aluminum heat sink 112, or the heat absorption element 112. The hot side of each Peltier element 118 is thermally coupled to the outer annular or oval heat sink 114. When the Peltier element 118 is operating, it cools the inner ring 112, and pumps the heat in the interior to the exterior environment through the outer annular/oval heat sink 114. Thermal contacts 116 are located directly on the very distal points in order to keep the temperature of the outer heat sink 114 from rising too high above the ambient temperature. Because a Peltier element 118 forms a heat pump without rotating parts, and therefore requires no maintenance, a silent cooling with an extended service life in comparison with that of a fan, and an economical price, can be obtained. This also supports a forced convection of air inside the housing 100 and consequently results in a uniform temperature increase in the housing 100, preventing a formation of hot spots, similar to with a rotary fan.

FIG. 2 shows a spatial illustration of a charger 200 for a vehicle according to an exemplary embodiment of the present invention. The charger 200 can be referred to as a power electronics system. The charger 200 has a housing 100 that substantially corresponds to the housing in FIG. 1. The housing 100 is also sealed in an airtight and moisture proof manner by a glass plate 202. The glass plate 202 has rounded corners. The housing 100 is thus substantially oval. The heat sink 110 encompasses the glass plate 202 in an annular manner. Only the outer part 114 is visible here. The interior space of the housing 100 is not visible, because it is concealed by the glass plate 202.

Operating elements 204 for operating the charger 200 and the display element 206 are integrated in the glass plate 202.

This technology can be used with any power electronics system 200 enclosed in a sealed, airtight and moisture proof plastic housing 100. The housing 100 can be in the shape of an oval, cylindrical, cubic, or even cuboid. Accordingly, the shapes of the heat absorbers and heat sinks 110 can be modified or adapted.

FIG. 3 shows an illustration of an attachment solution for a heat sink according to an exemplary embodiment of the present invention. The attachment solution is shown in a partial view of a housing 100 such as that shown in FIGS. 1 and 2, for example. The heat sink is attached via clip 300 that pass through the wall 108 of the housing 100. The clips have a flange 302 on one end, which bears on the wall 108. The clips 300 also have an internal thread 304, into which a screw is threaded when attaching the heat sink.

In other words, FIG. 3 shows a clip 300 with an internal threading 304 for attaching the heat sink to the sidewalls 108.

FIG. 4 shows a vehicle with a power electronics system 200 according to an exemplary embodiment. The power electronics system 200 contains a power electronics module that is enclosed in a housing, as described in reference to the preceding figures. According to this exemplary embodiment, the power electronics comprises a charger module, that is used for supplying an electric drive 402 in the vehicle with electricity.

If an exemplary embodiment comprises an “and/or” conjunction between a first feature and a second feature, this can be read to mean that the exemplary embodiment according to one embodiment contains both the first feature and the second feature, and according to another embodiment, comprises either just the first feature, or just the second feature.

### REFERENCE SYMBOLS

100 housing
102 power electronics
104 well
106 base
108 sidewall
110 heat sink
112 inner part
114 outer part
116 thermal bridge
118 Peltier element
120 control device
122 fins
200 charger, power electronics system
202 glass plate
204 operating element
206 display element
300 clip
302 flange
304 internal threading
400 vehicle
402 electric drive

1. A housing for accommodating power electronics for a vehicle, wherein the housing comprises the following features:
a well made of a plastic material;
a heat sink made of a thermally conductive metal material, wherein the heat sink comprises an inner part located on an inner surface of the well and an outer part located on an outer surface of the well; and
at least one Peltier element located between the inner part and the outer part.

2. The housing according to claim 1, in which a contact surface of the heat sink in contact with the well forms a contour of the well.

3. The housing according to claim 1, in which the heat sink is located on an edge of the well.

4. The housing according to claim 3, in which the heat sink encompasses the edge in an annular manner.

5. The housing according to claim 1, in which the heat sink is attached to the well by thermally conductive clips.

6. The housing according to claim 1, in which the well is sealed in an airtight manner by a glass plate.

7. The housing according to claim 1, in which the Peltier element is located on the inner surface of the well.

8. The housing according to claim 1, in which the heat sink has fins for enlarging the surface area thereof.

9. A power electronics system for a vehicle, wherein the power electronics system comprises a housing according to claim 1 further comprising power electronics, which are accommodated in an airtight manner inside the housing, wherein the Peltier element is connected to the power electronics such that it receives electricity, such that the inner part is cold and the outer part is warm when in operation.

10. The power electronics system according to claim 9, in which the power electronics forms a charger module for an electric drive of the vehicle.
